(19) United States
(12) Patent Application Publication
(10) Pub. No.: US 2012/0280680 A1
(43) Pub. Date: Nov. 8, 2012

(54) HALL INTEGRATED CIRCUIT PACKAGE

(76) Inventor: Kuei-Wei Kuo, Hsinchu County (TW)

(21) Appl. No.: 13/102,062

(22) Filed: May 6, 2011

(51) Int. Cl. G01R 33/06

(52) U.S. Cl. 324/251

(57) ABSTRACT

A Hall integrated circuit package includes a Hall integrated circuit and a field line guiding module. The Hall integrated circuit and the field line guiding module are assembled together with a connecting pin of the Hall integrated circuit exposed to outside. Magnetic field causing by carrying current of a cable passing through the field line guiding portion will be detected by the Hall integrated circuit more accurately so that current measurement based on the detection of magnetic field will be more sensitive and precise.

### FIELD OF THE INVENTION

The present invention relates to Hall integrated circuit, and particular to a Hall integrated circuit package having a field line guiding module which is easily deployed to a system and will cause no change and damage to original layout.

### DESCRIPTION OF THE PRIOR ART

Current measurement plays an important role in various electrical systems, especially for power consumption monitoring in modern market of eco-friendly. However, prior serial current measurement method invading to system is no longer a preferable choice for current measurement. For the requirement of non-destructive, precision, and convenience, the Hall effect devices are widely applied to systems for current measurement.

While applying prior Hall integrated circuit to a system for current measurement, an auxiliary for supporting the Hall integrated circuit and cable is needed. Also, magnetic field caused by carrying current of the cable is not detected efficiently by the Hall integrated circuit so that the precision and sensitivity of current measurement is lowered.

Therefore, the inventor provides the present invention based on experience in the field for overcoming the disadvantages mentioned above.

### BRIEF DESCRIPTION OF THE DRAWINGS

FIG. 1 is an exploded view showing the first embodiment of the present invention.

FIG. 2 is a schematic view showing the first embodiment of the present invention.

FIG. 3 is a schematic view showing an operation of the first embodiment of the present invention.

FIG. 4 is an exploded view showing the second embodiment of the present invention.

FIG. 5 is a schematic view showing the second embodiment of the present invention.

FIG. 6 is a schematic view showing an operation of the second embodiment of the present invention.

### SUMMARY OF THE PRESENT INVENTION

Accordingly, the primary object of the present invention is to provide a Hall integrated circuit package having a field line guiding module. Magnetic field caused by carrying current of a cable will be guided and detected by the Hall integrated circuit more sensitively and precisely.

To achieve above object, the present invention provides a Hall integrated circuit and a field line guiding module. The Hall integrated circuit and the field line guiding module are assembled together with a connecting pin of the Hall integrated circuit exposed to outside. Magnetic field causing by carrying current of a cable passing through the field line guiding portion will be detected by the Hall integrated circuit more accurately so that current measurement based on the detection of magnetic field will be more sensitive and precise.

### BRIEF DESCRIPTION OF THE DRAWINGS

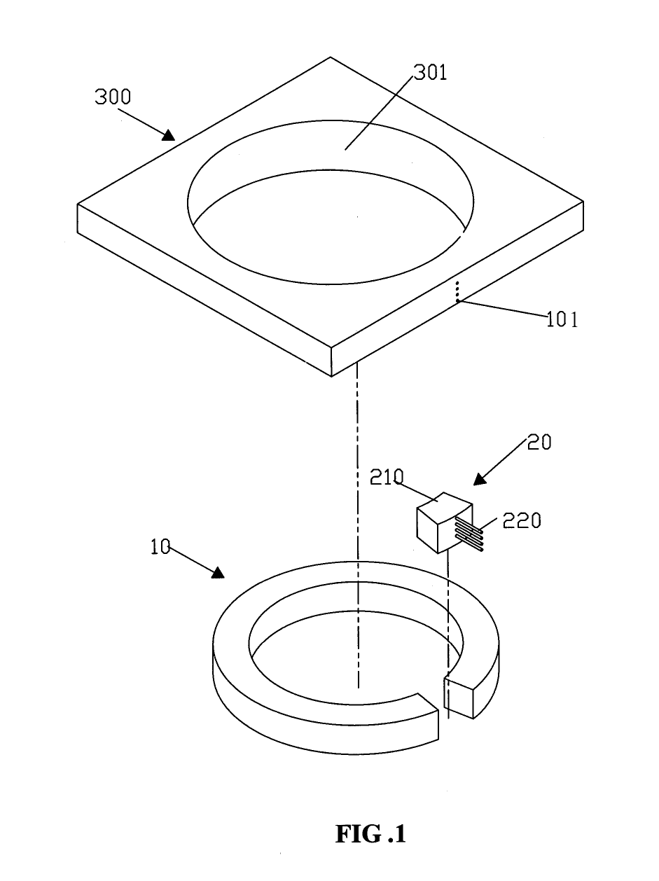

FIG. 1 is an exploded view showing the first embodiment of the present invention.

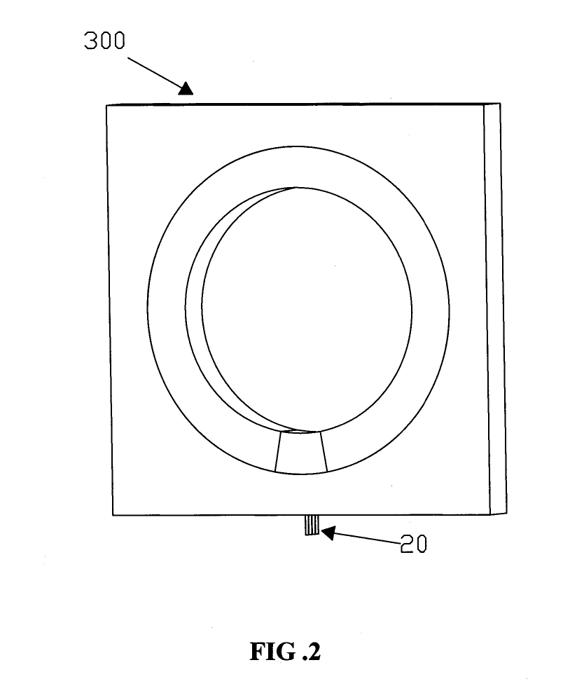

FIG. 2 is a schematic view showing the first embodiment of the present invention.

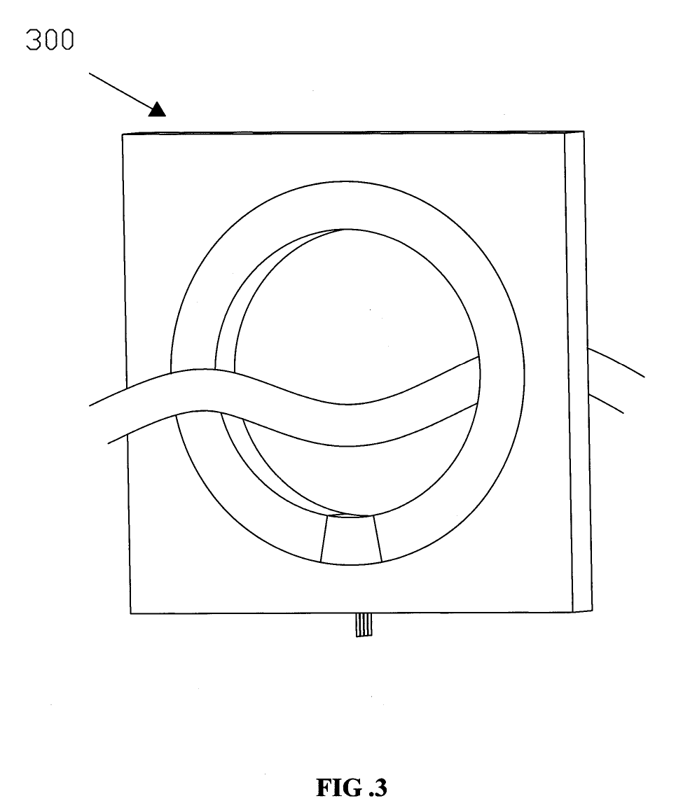

FIG. 3 is a schematic view showing an operation of the first embodiment of the present invention.

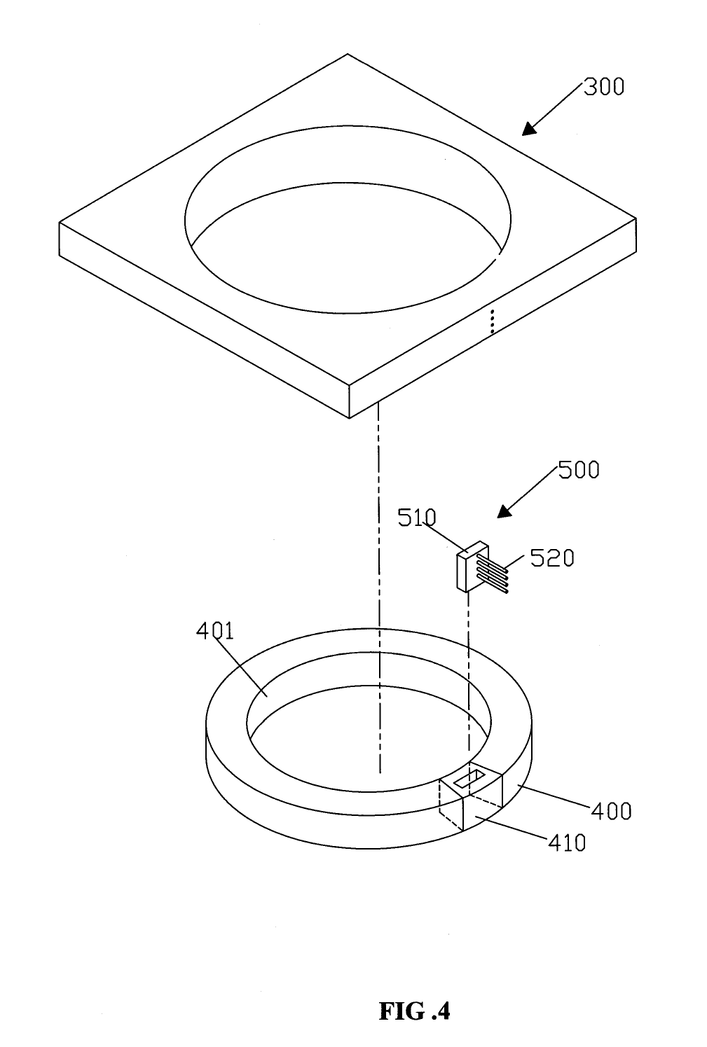

FIG. 4 is an exploded view showing the second embodiment of the present invention.

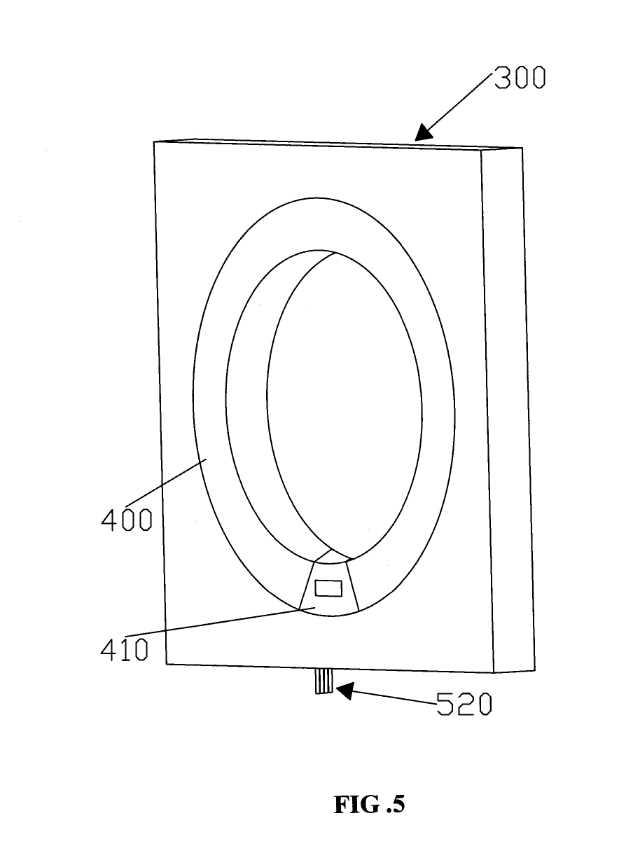

FIG. 5 is a schematic view showing the second embodiment of the present invention.

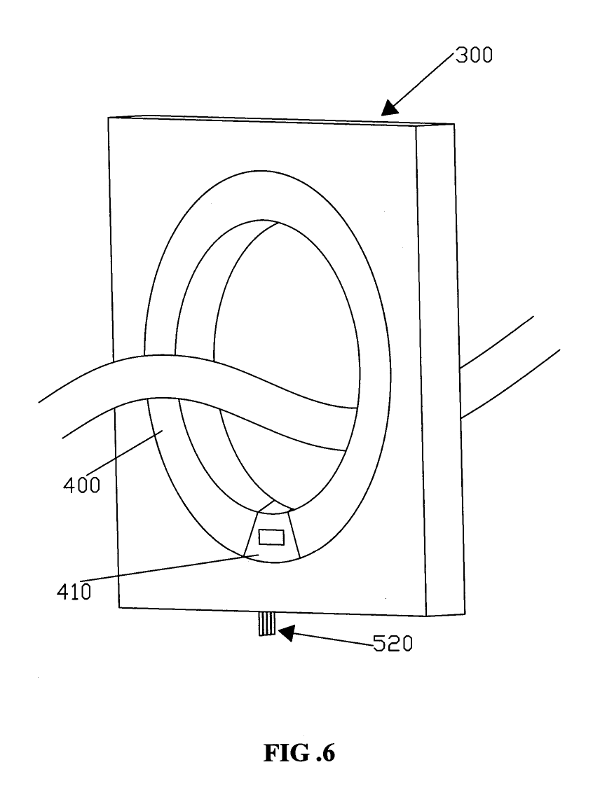

FIG. 6 is a schematic view showing an operation of the second embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

Referring to FIGS. 1 to 3, a preferable embodiment of a Hall integrated circuit package according to the present invention is illustrated.

The Hall integrated circuit package includes a field line guiding module 10 made of magnetical conducting material, Hall integrated circuit 20, and a casing 30.

The field line guiding module 10 is made of magnetical conducted material. The field line guiding module 10 and the Hall integrated circuit 20 are assembled together as a close loop for field line with a through hole 101 formed in the middle. A circle loop is formed in the present invention. The close loop formed by field line guiding module 10 and the Hall integrated circuit 20 can be other shape such as rectangle, oval, or irregular shape.

The Hall integrated circuit 20 includes a circuit 210 and connecting pin 220. The circuit 210 has a Hall effect sensor capable of sensing magnetic field generated by a cable carrying current. The connecting pin 220 includes a plurality of pin for electrically connecting the circuit 210 to external circuit for signal output.

The casing 30 serves to cover the field line guiding module 10 and the Hall integrated circuit 20, and the casing 30 has a opening 301 corresponding to the through hole 101 of the field line guiding module 10 so as to form a tunnel. The casing is preferably formed by insulating material.

The opening 301 of the casing 30 and the through hole 101 serve to be passed through by a cable carrying current. Magnetic field generated by the carrying current of the cable passing through the opening 301 and the through hole 101 will be detected by the Hall integrated circuit 20 so that a voltage signal corresponding to the current will be generated by the Hall integrated circuit 20 for current measurement. By the field line guiding module 10, the Hall integrated circuit 20 can detect the magnetic field more accurately so as to provide a precise current measurement.

The Hall integrated circuit 20 further includes a temperature compensating circuit (not shown).

The present invention provides the field line guiding module to efficiently gather the field line generated by the carrying current of the cable so that the Hall integrated circuit 20 can detect the field accurately. As shown in FIGS. 4 to 6, a second preferable embodiment of the present invention is illustrated.

The second embodiment of the present invention includes a field line guiding portion 400, a Hall integrated circuit 500, and a casing 300. The field line guiding portion 400 having a central through hole 410 is a close loop made of a magnetic conducting material. A circle loop is formed in the present invention. The close loop of field line guiding portion 400 can be other shape such as rectangle, oval, or other irregular shape. The Hall integrated circuit 500 includes a circuit 510 embedded inside the field line guiding portion 400 and a connecting pin 520 including a plurality of pin (which is normal 3 or 4). The connecting pin 520 serves to electrically connect the circuit 510 to external circuit for signal output. The connecting pin 520 is extending out of the field line guiding portion 400. The central through hole 410 serves to be passed through by a cable carrying current. Magnetic field generated by the carrying current of the cable passing through the through hole 410 will be detected by the Hall integrated circuit 500 so that a voltage signal corresponding to the current will be generated by the Hall integrated circuit 500 for current measurement. By the field line guiding portion 400, the Hall integrated circuit 500 can detected the magnetic field more accurately so as to provide a precise current measurement.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A Hall integrated circuit package comprising:
a Hall integrated circuit having a circuit detecting magnetic field and a connecting pin including a plurality of pin for connecting the circuit of the Hall integrated circuit to external circuit and signal output;
a field line guiding module made of magnetic conducting material; the field line guiding module and the Hall integrated circuit assembled together as a close loop for field line; the field line guiding module having a through hole in the middle thereof;
a casing covering the field line guiding module and the Hall integrated circuit; the casing having an opening corresponding to the through hole of the field line guiding module so as to form a tunnel;
wherein the Hall integrated circuit is arranged to the field line guiding module and the field line guiding module is covered by the casing; the connecting pin is exposed outside the casing; the opening of the casing and the through hole serve to be passed through by a cable carrying current; magnetic field generated by the carrying current of the cable will be detected by the Hall integrated circuit so that a signal corresponding to the current will be generated by the Hall integrated circuit for current measurement.

2. The Hall integrated circuit package as claimed in claim 1, wherein the magnetic conducting material is silicon steel.

3. The Hall integrated circuit package as claimed in claim 1, wherein the Hall integrated circuit includes a temperature compensating circuit.

4. The Hall integrated circuit package as claimed in claim 1, wherein the field line guiding module and the Hall integrated circuit are assembled as a close loop for field line; the shape of the close loop is one of a circle, rectangle, oval, or other irregular shape.

5. The Hall integrated circuit package as claimed in claim 1, wherein the casing is made of an insulating material.

6. The Hall integrated circuit package as claimed in claim 1, wherein the number of the pins of the connecting pin is 3 or 4.

7. A Hall integrated circuit package comprising:
a field line guiding portion made of magnetic conducting material having a central through hole; the field line guiding portion being a close loop for field line;
a Hall integrated circuit having a circuit embedded inside the field line guiding portion and a connecting pin exposed to outside of the field line guiding portion; the connecting pin connecting the circuit of the Hall integrated circuit to external circuit for signal output;
wherein magnetic field causing by carrying current of a cable passing through the central through hole of the field line guiding portion will be detected by the Hall integrated circuit so that a voltage signal is generated for current measurement.

8. The Hall integrated circuit package as claimed in claim 7, wherein the magnetic conducting material is silicon steel.

9. The Hall integrated circuit package as claimed in claim 7, wherein the Hall integrated circuit includes a temperature compensating circuit.

10. The Hall integrated circuit package as claimed in claim 7, wherein the field line guiding portion is shaped as one of a circle, rectangle, oval, or other irregular shape.

11. The Hall integrated circuit package as claimed in claim 7, wherein the number of the pins of the connecting pin is 3 or 4.
